(19) United States
(12) Patent Application Publication
(10) Pub. No.: US 2005/0024084 A1
(43) Pub. Date: Feb. 3, 2005

(54) Semiconductor integrated circuit and signal sending/receiving system

(75) Inventors: Takashi Hirata, Osaka (JP); Toru Iwata, Osaka (JP)

Correspondence Address: Jack Q. Lever, Jr.;McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/855,351

(22) Filed: May 28, 2004

(30) Foreign Application Priority Data
Jul. 30, 2003 (JP) 2003-282272

(51) Int. Cl. H03K 19/003

(52) U.S. Cl. 326/30

(57) ABSTRACT

A terminal resistor built in a signal-sending or signal-receiving semiconductor integrated circuit is composed of a parallel circuit of a polysilicon resistor element having excellent frequency characteristic and a P-type MOS transistor. The resistance value of the polysilicon resistor element is set so as to be an approximate value of the characteristic impedance of a transmission line to be connected. The gate voltage of the P-type MOS transistor is controlled by a gate bias voltage adjustment circuit. The resistance value of the P-type MOS transistor is variably adjusted. Variation in the resistance value of the polysilicon resistor element due to dispersion in its manufacturing process is absorbed by variably adjusting the resistance value of the P-type MOS transistor. The combined resistance value of the polysilicon resistor element and the P-type MOS transistor is adjusted with high precision just to the characteristic impedance of the transmission line. Thus, a signal-sending or signal-receiving semiconductor integrated circuit in which the terminal resistor having excellent frequency and DC characteristics is built can be obtained.

### BACKGROUND OF THE INVENTION

The present invention relates to a signal-sending or signal-receiving semiconductor integrated circuit and in particular to a signal-sending or signal-receiving semiconductor integrated circuit in which a terminal resistors is arranged at a sending terminal or a receiving terminal of a transmission line.

In a conventional signal sending/receiving system, when a sending section is connected to a receiving section by a transmission line, two terminal resistors are respectively connected to signal-sending and signal-receiving terminals of the transmission line and the resistance value of each terminal resistor is set to a value correspond to the characteristic impedance of the transmission line so that reflection at the signal-sending and signal-receiving terminals is reduced.

Recently, in association with high speed signal transmission, there has been a demand for further reduction of the signal reflection by setting the resistance value of each terminal resistor at the signal-sending and signal-receiving terminals with higher precision.

Though conventional terminal resistors are respectively arranged at the signal-sending and signal-receiving terminals of a transmission line, strictly speaking, there is a certain length of the transmission line from a signal-sending circuit to the terminal resistor on the signal-sending side. Further, there is a certain length of the transmission line from the terminal resistor on the signal-receiving side to the signal-receiving circuit. For this reason, parasitic capacities exist on the transmission line between the sending circuit and the terminal resistor on the signal-sending side and on the transmission line between the receiving circuit and the terminal resistor on the signal-receiving side, respectively, resulting in a decrease in quality of the waveform at the receiving circuit. Further, manufacturing costs for arranging the terminal resistors at sending and receiving terminals of a transmission line from outside is high.

For example, “A CMOS Serial Link for Fully Duplexed Data Communication” (Kyeongho Lee et al., IEEE JSSC (VOL. 30, NO. 4, APRIL 1995, pp. 353 to 363) discloses a conventional built-in terminal resistor provided within a semiconductor LSI. According to the publication, this built-in terminal resistor is composed of a MOS transistor. This MOS transistor is manufactured by the same manufacturing process as those of a large number of transistor elements to be provided within a semiconductor LSI at the same time when these elements are manufactured.

When the built-in MOS transistor is used as a terminal resistor as described above, its resistance value is greatly varied depending on its manufacturing process, an ambient temperature and a voltage to be applied. However, adjustment of the gate bias voltage of the MOS transistor can maintain the resistance value of the MOS transistor to a predetermined fixed value.

In recent days, signal transmission at even higher speed has been demanded and the terminal resistors at signal-sending and signal-receiving terminals have been desired to have excellent frequency characteristics.

From the standpoint of the frequency characteristic, because the built-in terminal resistor is composed of a MOS transistor, its frequency characteristic may be deteriorated due to its non-linearity as a resistance and the parasitic component of the MOS transistor. Thus, it is difficult to obtain an excellent frequency characteristic as expected. Moreover, because the terminal resistor is operated in a linear area (non-saturation area), its narrow operational range may present problems.

For example, it is considered to form a resistor element by polysilicon on or a diffusion layer on or in a semiconductor substrate for using the resultant resistor element as a terminal resistor. As the result of experiments by the present inventors, the resistor element had an excellent frequency characteristic. Nevertheless, the resistance value of this resistor element may be greatly varied depending on its manufacturing process, an ambient temperature and a voltage to be applied, as well as in a MOS transistor. As a result, it is difficult to obtain a resistor element which can accomplish a desired resistance value and has high precision.

### SUMMARY OF THE INVENTION

An object of the present invention is to obtain a terminal resistor which can obtain a desired resistance value, and has high precision and excellent DC and frequency characteristics as a built-in terminal resistor provided in a signal-sending or signal-receiving semiconductor LSI.

In order to accomplish the aforementioned object, according to the present invention, a combination of a transistor and a resistor element formed of polysilicon having an excellent frequency characteristic on a semiconductor substrate or a diffusion layer having an excellent frequency characteristic in the semiconductor substrate is used as a built-in terminal resistor within a signal-sending or signal-receiving semiconductor LSI. While ensuring the excellent frequency characteristic of the resistor element formed of polysilicon or the like on or in the semiconductor substrate, dispersion of the resistor element formed of polysilicon or the like on or in the semiconductor substrate is finely adjusted by adjusting the bias of the control terminal of the transistor, so that an expected resistance value is set. Thus, a semiconductor LSI with effectively less reflection of transmission signals at the signal-sending or receiving terminal can be provided.

The aforementioned object of the present invention is to provide a terminal resistor having excellent frequency and DC characteristics. Such a resistor element having the excellent characteristics can be widely utilized as a constant resistor element as well as a terminal resistor. Thus, another object of the present invention is to use such a resistor element as a constant resistor element for other applications.

That is, the present invention provides a semiconductor integrated circuit for sending or receiving a signal through a transmission line, including inside thereof a terminal resistor arranged on sending or receiving side of the transmission line, wherein the terminal resistor includes a first resistor element and a second resistor element connected to the first resistor element, the first resistor element is composed of a resistor element formed on or in a semiconductor substrate, a resistance value of the resistor element formed on or in the semiconductor substrate being set so as to be an approximate value of a characteristic impedance of the transmission line, the second resistor element is composed of a transistor, a bias voltage adjustment circuit is connected to a control terminal of the transistor for adjusting a bias voltage of the control terminal, and a resistance value of the transistor is adjusted by the bias voltage adjustment circuit so as to adjust a combined resistance value of the first resistor element and the second resistor element just to the characteristic impedance of the transmission line.

According to the present invention, in the semiconductor integrated circuit, the resistor element formed on or in the semiconductor substrate is connected in parallel to the transistor.

According to the present invention, in the semiconductor integrated circuit, a lower limit value of dispersion of the resistance value of the resistor element formed on or in the semiconductor substrate is set so as to be equal to or larger than a lower limit value of dispersion of an expected combined resistance value of the first resistor element and the second resistor element.

According to the present invention, in the semiconductor integrated circuit, the resistor element formed on or in the semiconductor substrate is serially connected to the transistor.

According to the present invention, in the semiconductor integrated circuit, the resistance value of the resistor element formed on or in the semiconductor substrate is set so as to be larger than the resistance value of the transistor.

According to the present invention, in the semiconductor integrated circuit, the resistor element formed on or in the semiconductor substrate includes first and second partial resistor elements, the first partial resistor element composes a series circuit together with the transistor, and the second partial resistor element is connected in parallel to the series circuit.

According to the present invention, in the semiconductor integrated circuit, a lower limit value of dispersion of a resistance value of the second partial resistor element is set so as to be equal to or larger than a lower limit value of dispersion of an expected combined resistance value of the first resistor element and the second resistor element.

According to the present invention, in the semiconductor integrated circuit, the bias voltage adjustment circuit includes: a replica circuit having the same structure as that of the terminal resistor; a constant current source for applying a predetermined constant current to the replica circuit; and an operational amplifier, the operational amplifier feedback-controlling the bias voltage of the control terminal of the transistor so that the amount of voltage drop generated in the replica circuit is equal to a predetermined reference potential.

The present invention also provides a signal sending/receiving system including: the two semiconductor integrated circuits as above respectively for signal-sending and signal-receiving; and a transmission line connected to the signal-sending semiconductor integrated circuit and the signal-receiving semiconductor integrated circuit.

The present invention also provides a semiconductor integrated circuit including inside thereof a constant resistor element formed of a semiconductor element, wherein the constant resistor element includes a first resistor element and a second resistor element connected to the first resistor element, the first resistor element is composed of a resistor element formed on or in a semiconductor substrate, a resistance value of the resistor element formed on or in the semiconductor substrate being set so as to be an approximate value of an expected value, the second resistor element is composed of a transistor, a bias voltage adjustment circuit is connected to a control terminal of the transistor for adjusting a bias voltage of the control terminal, and a resistance value of the transistor is adjusted by the bias voltage adjustment circuit so as to adjust a combined resistance value of the first resistor element and the second resistor element just to the expected value.

According to the present invention, in the semiconductor integrated circuit, the resistor element formed on or in the semiconductor substrate is a polysilicon resistor element.

According to the present invention, in the semiconductor integrated circuit, the resistor element formed on or in the semiconductor substrate is a diffusion resistor element.

As described above, according to the present invention, the first resistor element is composed of the resistor element formed on or in the semiconductor substrate, such as a polysilicon resistor element, a diffusion resistor element, which has an excellent frequency characteristic, and its resistance value is set so as to be an approximate value of an expected value, e.g., the characteristic impedance of the transmission line. Thus, a built-in terminal resistor having an excellent frequency characteristic can be obtained. The resistance value of the resistor element formed on or in the semiconductor substrate, such as the polysilicon resistor element, the diffusion resistor element, is varied depending on its manufacturing process and an ambient temperature. Nevertheless, the bias voltage of the control terminal of the transistor serving as the second resistor element is adjusted by the variation, so as to finely adjust the resistance value of the transistor, with a result that the variation in the resistance value of the resistor element formed on or in the semiconductor substrate, such as the polysilicon resistor element, is absorbed by the fine adjustment of the resistance value of the transistor. Thus, the combined resistance value of the transistor and the resistor element formed on the semiconductor substrate such as the polysilicon resistor element agrees with the expected value (characteristic impedance of transmission line) with high precision and an excellent DC characteristic can be obtained. Consequently, a terminal resistor having excellent frequency and DC characteristics can be obtained as a built-in terminal resistor.

### BRIEF DESCRIPTION OF THE DRAWINGS

FIG. 1 is a circuit diagram illustrating the overall schematic structure of a signal sending/receiving system relating to an embodiment of the present invention.

FIG. 2 is a circuit diagram illustrating the specific structure of a built-in terminal resistor.

FIG. 3 is a vertical sectional view of the structure of a polysilicon resistor element.

FIG. 4 is a vertical sectional view of the structure of a P-type MOS transistor.

FIG. 5 is a circuit diagram illustrating the internal structure of a gate bias voltage adjustment circuit.

FIG. 6 is a circuit diagram illustrating the specific structure of a first modified example of the built-in terminal resistor.

FIG. 7 is a circuit diagram illustrating the specific structure of a second modified example of the built-in terminal resistor.

### DETAILED DESCRIPTION OF THE INVENTION

Preferred embodiments of the present invention will be described hereinafter with reference to the drawings.

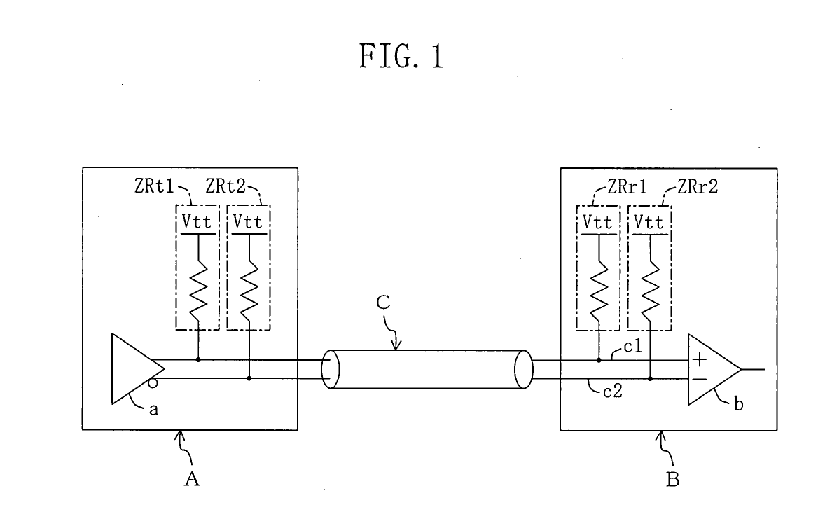

FIG. 1 illustrates the overall structure of a signal sending/receiving system according to the embodiments of the present invention. Referring to FIG. 1, a reference character A indicates a signal-sending semiconductor integrated circuit and a reference character B indicates a signal-receiving semiconductor integrated circuit. A reference character C indicates a transmission line which connects the signal-sending semiconductor integrated circuit A and the signal-receiving semiconductor integrated circuit B and is formed of a differential cable or a wiring formed on a printed wiring board (which will be represented by cable hereinafter). A signal is transmitted from an output driver a provided in the signal-sending semiconductor integrated circuit A to the transmission line C. Then, the signal is received by a receiver b in the signal-receiving semiconductor integrated circuit B.

In the signal-sending semiconductor integrated circuit A, built-in terminal resistors ZRt1 and ZRt2 are arranged subsequent to the output driver a so as to respectively correspond to two cables c1 and c2 composing the differential cable of the transmission line C. In the signal-receiving semiconductor integrated circuit B, built-in terminal resistors ZRr1 and ZRr2 are arranged before the receiver b so as to respectively correspond to the two cables c1 and c2 composing the differential cable of the transmission line C. These built-in terminal resistors ZRt1, ZRt2, ZRr1 and ZRr2 are manufactured in the same manufacturing process as those of built-in semiconductor elements composing the built-in output driver a and receiver b at the same time when such elements are manufactured.

Suppose that resistance values of the built-in terminal resistors ZRt1, ZRt2, ZRr1 and ZRr2 are ZR and the characteristic impedance of the transmission line C is Z. If the resistance value ZR is not equal to the characteristic impedance Z (ZR≠Z), a signal propagated in the transmission line C is reflected at the receiving terminal thereof at the rate of the reflection coefficient Γ represented by the following expression.
Γ=(ZR−Z)/(ZR+Z)

Because these four built-in terminal resistors ZRt1, ZRt2, ZRr1 and ZRr2 have the same internal structure, the internal structure of the built-in terminal resistor ZRr1 within the signal-receiving semiconductor integrated circuit B will be described hereinafter.

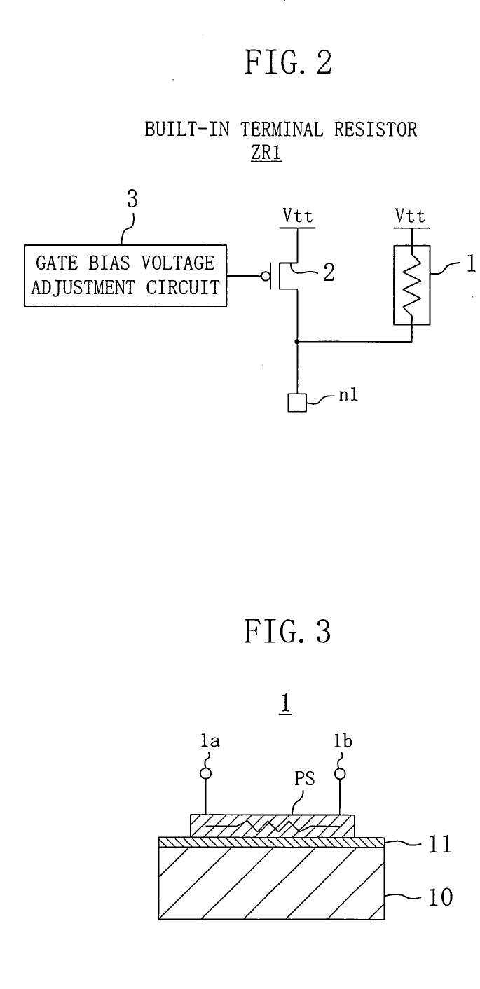

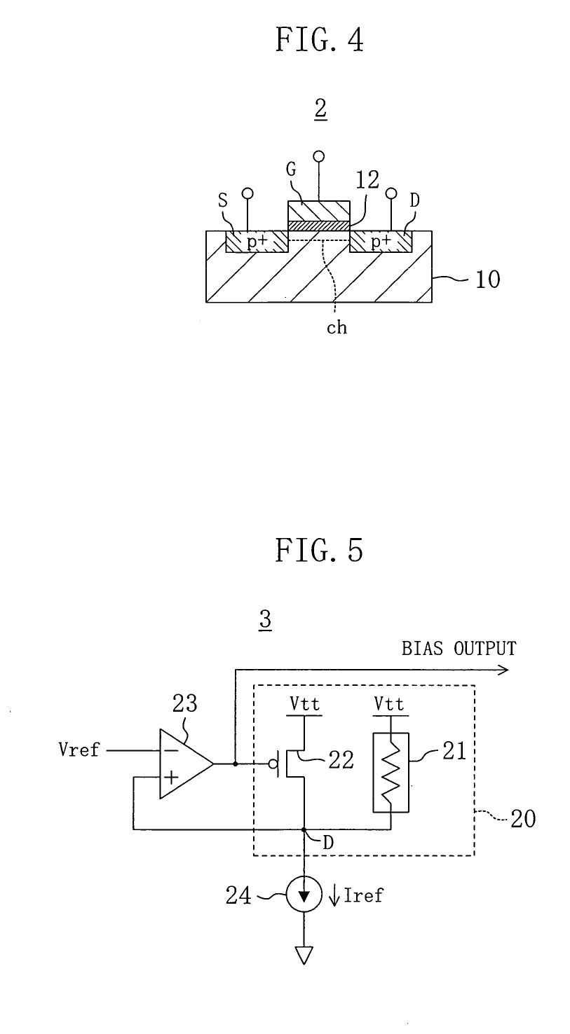

FIG. 2 illustrates the internal structure of the built-in terminal resistor ZRr1. Referring to FIG. 2, a reference numeral 1 indicates a polysilicon resistor element (first resistor element) made of polysilicon and a reference numeral 2 a P-type MOS transistor (second resistor element). As illustrated in FIG. 3, the polysilicon resistor element 1 is formed of a polysilicon PS formed above, for example, an n-type semiconductor substrate 10 with an oxide film 11 being interposed therebetween. The resistance value Rps of the polysilicon resistor element is set to be an approximate value of the characteristic impedance Z of the transmission line C. The polysilicon PS is provided with two connection nodes 1a and 1b. The P-type MOS transistor 2 includes, as illustrated in FIG. 4, a source S and a drain D which are formed on the upper portion of the n-type semiconductor substrate 10 and a gate (control terminal) G which is arranged above a channel ch formed between the source S and the drain D with a gate oxide film 12 being interposed therebetween. The channel ch is used as a resistor.

Referring to FIG. 2, one end of the polysilicon resistor element 1 is connected to a power source Vtt and the other end thereof is connected to a node n1. The source node of the P-type MOS transistor 2 is connected to the power source Vtt and the drain node thereof is connected to the node n1, so that the P-type MOS transistor 2 is connected in parallel to the polysilicon resistor element 1. The gate node of the P-type MOS transistor 2 is connected to the output node of a gate bias voltage adjustment circuit 3. The gate bias voltage adjustment circuit 3 adjusts the gate bias voltage of the P-type MOS transistor 2, so as to adjust the resistance value of the P-type MOS transistor 2.

The resistance value of the polysilicon resistor element 1 is dispersed greatly due to variations in the semiconductor manufacturing process. Thus, it is difficult to manufacture the polysilicon resistor element having a resistance value precisely equal to, by itself, the characteristic impedance Z of the transmission line C. For this reason, the resistance value of the polysilicon resistor element 1 is finely adjusted by controlling the gate bias voltage of the P-type MOS transistor 2 connected in parallel to the polysilicon resistor element 1 by the gate bias voltage adjustment circuit 3, whereby a resistance value between the power source Vtt and the node n1, i.e., a combined resistance value of the polysilicon resistor element 1 and the P-type MOS transistor 2 connected in parallel is adjusted with high precision to the characteristic impedance Z (expected value) of the transmission line C.

Next, the internal structure of the gate bias voltage adjustment circuit 3 shown in FIG. 2 is illustrated in FIG. 5. Referring to FIG. 5, a reference numeral 20 indicates a replica circuit having the same structure as that of the built-in terminal resistor in FIG. 2 composed of the parallel circuit of the polysilicon resistor element 1 and the P-type MOS transistor 2. In other words, the replica circuit 20 has a parallel circuit of a polysilicon resistor element 21 and a P-type MOS transistor 22 and has a node D which is the same as the node n1 of the terminal resistor in FIG. 2. The polysilicon resistor element 21 and the P-type MOS transistor 22 are manufactured by the same manufacturing process as those of the polysilicon resistor element 1 and the P-type MOS transistor 2 composing the terminal resistor at the same time when such components are manufactured. Desirably, the polysilicon resistor element 21 and the P-type MOS transistor 22 are manufactured in vicinities of these elements 1 and 2. The resistance value Rps of the polysilicon resistor element 21 is an approximate value of the resistance value Rps of the polysilicon resistor element 1 composing a part of the terminal resistor. The resistance value Rtr of the P-type MOS transistor 22 is an approximate value of the resistance value Rtr of the P-type MOS transistor 2 composing a part of the terminal resistor.

In the gate bias voltage adjustment circuit 3 illustrated in FIG. 5, a reference numeral 23 indicates an operational amplifier and a reference numeral 24 indicates a constant current source. The constant current source 24 applies a constant current Iref from the power source Vtt to the ground through the parallel circuit of the polysilicon resistor element 21 and the P-type MOS transistor 22 and through the node D. The operational amplifier 23 is so arranged that a reference potential Vref is input to the minus node thereof, the potential of the node D is input to the plus node thereof and the output node thereof is connected to the gate node of the P-type MOS transistor 22 of the replica circuit 20, whereby the gate bias voltage of the P-type MOS transistor 22 is feedback-controlled so that the potential of the node D, i.e., the amount of voltage drop generated in the replica circuit 20 becomes equal to the reference potential Vref. At this time, a combined resistance value Rt of the power source Vtt and the node D is expressed as Rt=(Vtt−Vref)/Iref. Accordingly, it is found that in order to obtain an expected value Rto, appropriate values are respectively set for the source voltage Vtt, the reference potential Vref and the constant current Iref. Since the output node of the gate bias voltage adjustment circuit 3 is also connected to the gate node of the P-type MOS transistor 2 composing a part of the terminal resistor illustrated in FIG. 2, the combined resistance value of the power source Vtt and the node n1 illustrated in FIG. 2 becomes also the expected value Rto. With this structure, the resistance value of the built-in terminal resistor can be automatically adjusted to the expected value Rto.

As an example, a description will be given in which actual resistance values are applied to this embodiment. Suppose that the expected resistance value Rto of the built-in terminal resistor is 50 Ω±10% and the variation in the manufacturing process for the polysilicon resistor element 1 is ±15%. When the resistance value of the polysilicon resistor element 1 is 53 Ω (the range of dispersion: 53 Ω±15%), the expected resistance value Rto can be realized by setting the size of the P-type MOS transistor 2 and the operational range of the gate bias voltage adjustment circuit 3 so that the resistance value of the P-type MOS transistor 2 can be adjusted within the range of 277 Ω to ∞. When the expected resistance value Rto is 50 Ω±5% and the resistance value of the polysilicon resistor element 1 is 56 Ω (the range of dispersion: 56 Ω±15%), on1y the resistance value of the P-type MOS transistor 2 is set within the range of 217 Ω to ∞.

In the aforementioned examples, since the resistance value of the polysilicon resistor element 1 is much more dominant than that of the P-type MOS transistor 2 in 50 Ω of the expected resistance value, influences of the parasitic component of the P-type MOS transistor 2 can be suppressed in comparison with the case of a terminal resistor composed on1y of the P-type MOS transistor 2. As a result, the frequency characteristic of the built-in terminal resistor ZRr1 is improved. Further, by adjusting the resistance value of the P-type MOS transistor 2, influences of the variation in the manufacturing process for the device resistors can be absorbed. Moreover, since the resistance value of the polysilicon resistor element 1 is designed so that the lower limit value of dispersion of the polysilicon resistor element 1 is equal to or larger than the lower limit value of dispersion of the expected resistance value Rto, the size of the P-type MOS transistor 2 can be reduced. Consequently, influence of the P-type MOS transistor 2 can be minimized and thus the frequency characteristic of the terminal resistor is further improved.
(First Modified Example of Built-in Terminal Resistor)

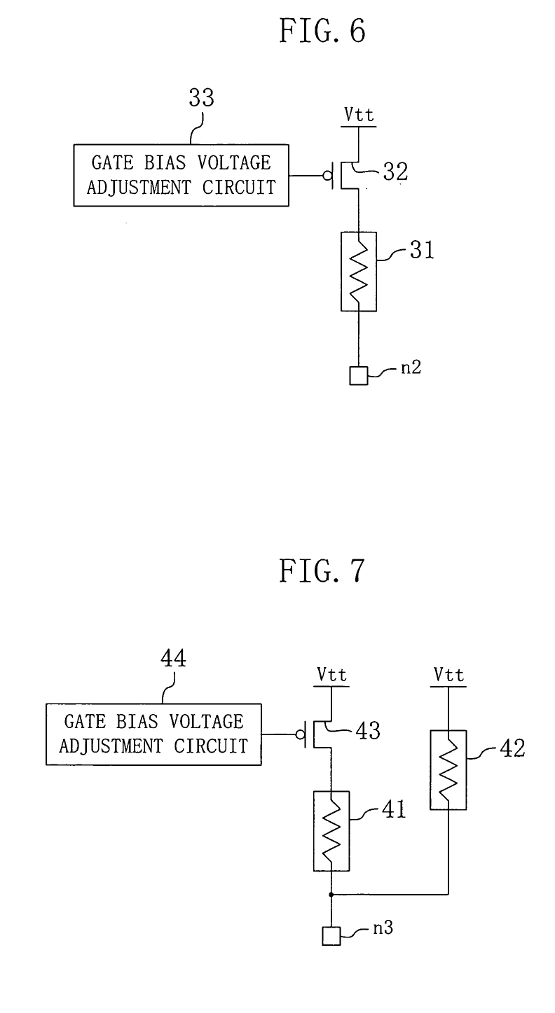

A first modified example of the built-in terminal resistor will be described in detail with reference to FIG. 6.

FIG. 6 illustrates a built-in terminal resistor according to this modified example. Referring to FIG. 6, a reference numeral 31 indicates a polysilicon resistor element, a reference numeral 32 indicates a P-type MOS transistor and a reference numeral 33 indicates a gate bias voltage adjustment circuit for adjusting and controlling the gate bias voltage of the P-type MOS transistor 32.

The source node of the P-type MOS transistor 32 is connected to the power source Vtt, the drain node thereof is connected to one end of the polysilicon resistor element 31 and the gate node thereof is connected to the output node of the gate bias voltage adjustment circuit 3. The other end of the polysilicon resistor element 31 is connected to a node n2. The gate bias voltage adjustment circuit 33 controls the gate bias voltage of the P-type MOS transistor 32 so that the resistance value between the power source Vtt and the node n2 becomes the expected resistance value Rto. As in the above-described embodiment, the resistance value of the polysilicon resistor element 31 is dispersed due to the variation in the manufacturing process. Thus, the resistance value of the P-type MOS transistor 32 is adjusted by controlling the gate bias voltage of the P-type MOS transistor 32 by the gate bias voltage adjustment circuit 33. The gate bias voltage adjustment circuit 33 can be realized by using the same structure as that of the adjustment circuit 3 illustrated in FIG. 5. Here, the replica circuit 20 is substituted by a serial circuit of the polysilicon resistor element 31 and the P-type MOS transistor 32, which composes the terminal resistor illustrated in FIG. 6.

For example, suppose that the expected resistance value of the terminal resistor is 50 Ω±10% and the variation in the manufacturing process for the polysilicon resistor element 31 is 15%. When the resistance value of the polysilicon resistor element 31 is set to 40 Ω (the range of dispersion: 40 Ω±15%), on1y the size of the P-type MOS transistor 32 and the operational range of the gate bias voltage adjustment circuit 33 are designed so that the resistance value of the P-type MOS transistor 32 can be controlled in the range of 9 Ω to 16 Ω at the lowest. When the expected resistance value of the terminal resistor is 50 Ω±5% by taking the variation in the manufacturing process for the gate bias voltage adjustment circuit 33 into a consideration, on1y the controllable range of the resistance value of the P-type MOS transistor 32 is set to 6.5 Ω to 16 Ω, which is a designable range.

According to this modified example, the resistance value of the polysilicon resistor element 31 is set to be larger than that of the P-type MOS transistor 32 with respect to the expected resistance value Rto, so that the resistance value of the polysilicon resistor element 31 is dominant in the resistance value of the terminal resistor. Thus, the influences of the parasitic component of the P-type MOS transistor 32 can be suppressed in comparison with the case of a terminal resistor on1y by the P-type MOS transistor. Accordingly, the frequency characteristic of the terminal resistor is improved. Further, by adjusting the resistance value of the P-type MOS transistor 32, the influences of the variation in the manufacturing process for the device resistors can be absorbed.

In comparison with the built-in terminal resistor in the above-described embodiment, a voltage applied between the source and the drain of the P-type MOS transistor 32 becomes smaller. Thus, the P-type MOS transistor 32 hardly falls in a saturation region and the linear V-I characteristic (linearity of resistance value) is improved. In the case of several tens Ω of the expected resistance value, however, the resistance value of the P-type MOS transistor 32 must be lowered to a few Ω and the size of the transistor must be increased, resulting in an increase in area. Further, the AC characteristic may be deteriorated.
(Second Modified Example of Built-in Terminal Resistor)

Next, a second modified example of the built-in terminal resistor will be described in detail with reference to FIG. 7.

FIG. 7 illustrates a built-in terminal resistor of this modified example. Referring to FIG. 7, reference numerals 41 and 42 respectively indicate first and second polysilicon resistor elements (first and second partial resistor elements composing first resistor element), a reference numeral 43 indicates a P-type MOS transistor (second resistor element) and a reference numeral 44 indicates a gate bias voltage adjustment circuit for adjusting and controlling the gate bias voltage of the P-type MOS transistor 43. The source node of the P-type MOS transistor 43 is connected to the power source Vtt, the drain node thereof is connected to one end of the first polysilicon resistor element 41. Thus, the P-type MOS transistor 43 is serially connected to the first polysilicon resistor element 41. The gate node of the P-type MOS transistor 43 is connected to the output node of the gate bias voltage adjustment circuit 44. The other end of the first polysilicon resistor element 41 is connected to a node n3. One end of the second polysilicon resistor element 42 is connected to the power source Vtt and the other end thereof is connected to the node n3. Thus, the second polysilicon resistor element 42 is connected in parallel to the serial circuit of the P-type MOS transistor 43 and the first polysilicon resistor element 41. The gate bias voltage adjustment circuit 44 adjusts and controls the gate bias voltage of the P-type MOS transistor 43 so that the resistance value between the power source Vtt and the node n3 becomes the expected resistance value Rto (i.e., characteristic impedance Z).

As in the above-described embodiment, the resistance values of these two polysilicon resistor elements 41 and 42 are dispersed due to the variation in the manufacturing process. Thus, the resistance value of the P-type MOS transistor 43 is adjusted by adjusting and controlling the gate bias voltage of the P-type MOS transistor 43 by the adjustment circuit 44, so that the resistance value between the power source Vtt and the node n3 is adjusted to the expected value Rto with high precision. The gate bias voltage adjustment circuit 44 in this second modified example is also realized by using the same structure as that of the bias voltage control circuit 3 in the above-described embodiment (see FIG. 5). Referring to the replica circuit 20, its structure is substituted by the same structure as that of the built-in terminal resistor illustrated in FIG. 7, i.e., the structure in which the second polysilicon resistor element 42 is connected in parallel to the serial circuit of the P-type MOS transistor 43 and the first polysilicon resistor element 41.

In this modified example, suppose, for example, that the expected resistance value of the built-in terminal resistor is 50 Ω±10% and the variation in the manufacturing process for the polysilicon resistor elements 41 and 42 is ±15%. When the resistance value of the second polysilicon resistor element 42 is 53 Ω (the range of dispersion: 53 Ω±15%), the expected resistance value can be realized only by appropriately setting the resistance value of the first polysilicon resistor element 41, the size of the P-type MOS transistor 43 and the operational range for the gate bias voltage adjustment circuit 44 by the same method as in the first modified example so that the serial resistance value of the P-type MOS transistor 43 and the first polysilicon resistor element 41 can be adjusted to 277 Ω to ∞.

In the case of 50 Ω±5% of the expected resistance value, when the resistance value of the second polysilicon resistor element 42 is 56 Ω (the range of dispersion: 56 Ω±15%), only the serial resistance value of the P-type MOS transistor 43 and the first polysilicon resistor element 41 is set to 273 Ω to ∞.

According to this example, since the resistance value of the second polysilicon resistor element 42 is dominant in 50 Ω of the expected resistance value, the influences of the parasitic component of the P-type MOS transistor 43 can be suppressed in comparison with the case of a terminal resistor composed of only the P-type MOS transistor 43. Thus, the frequency characteristic of the terminal resistor is improved. Further, by adjusting the resistance value of the P-type MOS transistor 43, the influences of the variation in the manufacturing process for the device resistors can be absorbed. Moreover, by designing the resistance value of the second polysilicon resistor element 42 so that the lower limit value of dispersion of the second polysilicon resistor element 42 approximates to the lower limit value of dispersion of the expected resistance value Rto, the range that the resistance value of the P-type MOS transistor 43 can be changed can be limited to be smaller and the size of the transistor can be minimized. As a result, the influence of the P-type MOS transistor 43 is minimized and the frequency characteristic of the terminal resistor is improved.

Especially according to this second modified example, the size of the P-type MOS transistor 43 is increased a little in comparison with the above-described embodiment but the linear V-I characteristic (linearity of resistance value) is improved as described in the first modified example.

In the above description, the P-type MOS transistor is used as a transistor (second resistor element) capable of finely adjusting the resistance value but an N-type MOS transistor and transistors other than the MOS type may be used. In the above descriptions, the polysilicon resistor elements 1, 31, 41, and 42 are used as the first resistor element formed on the semiconductor substrate 10. However, in order to lower the resistance value thereof, these polysilicon resistor elements may be silicide polysilicon resistor elements formed in such a manner that a metal silicide is deposited on polysilicon PS, which is the material of the resistor element, or may be non-silicide polysilicon resistor elements to which no metal silicide is deposited. Further, the polysilicon resistor elements 1, 31, 41 and 42 have superior frequency characteristic to that of a transistor. Thus, such resistor elements are equivalent to and can be substituted by resistor elements having an excellent frequency characteristic equivalent to those of the polysilicon resistor elements or other resistor elements, such as a diffusion resistor element, formed on or in the semiconductor substrate.

Although the present invention is applied to both the signal-sending and signal-receiving semiconductor integrated circuits A and B in the embodiment, the present invention may be applied to only one of them.

Further, the case of applying the present invention to the signal-sending and signal-receiving semiconductor integrated circuits A and B has been illustrated in the embodiment. While, the present invention can be applied to a semiconductor integrated circuit with a constant resistance circuit therein by employing the built-in terminal resistor as the constant resistance circuit since the present invention can adjust the resistance value of a built-in terminal resistor to an expected value with high precision

1. A semiconductor integrated circuit for sending or receiving a signal through a transmission line, comprising inside thereof a terminal resistor arranged on sending or receiving side of said transmission line, wherein
said terminal resistor includes a first resistor element and a second resistor element connected to said first resistor element,
said first resistor element is composed of a resistor element formed on or in a semiconductor substrate, a resistance value of said resistor element formed on or in the semiconductor substrate being set so as to be an approximate value of a characteristic impedance of said transmission line,
said second resistor element is composed of a transistor,
a bias voltage adjustment circuit is connected to a control terminal of said transistor for adjusting a bias voltage of the control terminal, and
a resistance value of said transistor is adjusted by said bias voltage adjustment circuit so as to adjust a combined resistance value of said first resistor element and said second resistor element just to the characteristic impedance of said transmission line.

2. The semiconductor integrated circuit of claim 1, wherein said resistor element formed on or in the semiconductor substrate is connected in parallel to said transistor.

3. The semiconductor integrated circuit of claim 2, wherein a lower limit value of dispersion of the resistance value of said resistor element formed on or in the semiconductor substrate is set so as to be equal to or larger than a lower limit value of dispersion of an expected combined resistance value of said first resistor element and said second resistor element.

4. The semiconductor integrated circuit of claim 1, wherein said resistor element formed on or in the semiconductor substrate is serially connected to said transistor.

5. The semiconductor integrated circuit of claim 4, wherein the resistance value of said resistor element formed on or in the semiconductor substrate is set so as to be larger than the resistance value of said transistor.

6. The semiconductor integrated circuit of claim 1, wherein said resistor element formed on or in the semiconductor substrate includes first and second partial resistor elements,
said first partial resistor element composes a series circuit together with said transistor, and
said second partial resistor element is connected in parallel to said series circuit.

7. The semiconductor integrated circuit of claim 6, wherein a lower limit value of dispersion of a resistance value of said second partial resistor element is set so as to be equal to or larger than a lower limit value of dispersion of an expected combined resistance value of said first resistor element and said second resistor element.

8. The semiconductor integrated circuit of claim 1, wherein said bias voltage adjustment circuit includes:
a replica circuit having the same structure as that of said terminal resistor;
a constant current source for applying a predetermined constant current to said replica circuit; and
an operational amplifier, said operational amplifier feedback-controlling the bias voltage of the control terminal of said transistor so that the amount of voltage drop generated in said replica circuit is equal to a predetermined reference potential.

9. A signal sending/receiving system comprising:
two semiconductor integrated circuits according to claim 1 respectively for signal-sending and signal-receiving; and
a transmission line connected to said signal-sending semiconductor integrated circuit and said signal-receiving semiconductor integrated circuit.

10. A semiconductor integrated circuit comprising inside thereof a constant resistor element formed of a semiconductor element, wherein
said constant resistor element includes a first resistor element and a second resistor element connected to said first resistor element,
said first resistor element is composed of a resistor element formed on or in a semiconductor substrate, a resistance value of said resistor element formed on or in the semiconductor substrate being set so as to be an approximate value of an expected value,
said second resistor element is composed of a transistor,
a bias voltage adjustment circuit is connected to a control terminal of said transistor for adjusting a bias voltage of the control terminal, and
a resistance value of said transistor is adjusted by said bias voltage adjustment circuit so as to adjust a combined resistance value of said first resistor element and said second resistor element just to the expected value.

11. The semiconductor integrated circuit of claim 1, wherein said resistor element formed on or in the semiconductor substrate is a polysilicon resistor element.

12. The semiconductor integrated circuit of claim 10, wherein said resistor element formed on or in the semiconductor substrate is a polysilicon resistor element.

13. The semiconductor integrated circuit of claim 1, wherein said resistor element formed on or in the semiconductor substrate is a diffusion resistor element.

14. The semiconductor integrated circuit of claim 10, wherein said resistor element formed on or in the semiconductor substrate is a diffusion resistor element.
